(19) United States
(12) Patent Application Publication
(10) Pub. No.: US 2005/0087222 A1
(43) Pub. Date: Apr. 28, 2005

(54) Device for producing electric energy

(76) Inventor: Bernhard Muller-Werth, Sulzbach (DE)

Correspondence Address: Friedrich Kueffner, Suite 910, 317 Madison Avenue, New York, NY, 10017, US

(21) Appl. No.: 10/938,392

(22) Filed: Sep. 11, 2004

(30) Foreign Application Priority Data
Sep. 15, 2003 (DE) 103 42 653.1

(51) Int. Cl. H01L 35/28

(52) U.S. Cl. 136/224

(57) ABSTRACT

A device for producing electric energy includes a plurality of thermocouples, each of which has a first conductor element, a second conductor element connected witht he first conductor element, and a third conductor element connected with the second conductor element on the opposite side of the second conductor element from the first conductor element. The conductive material of the fist and third conductor elements is different from the conductive material of the second conductor elements; the first conductor elements are connected with a heat source, and the third conductor elements are connected with a heat sink. A bank of thermocouples is provided, in which the first and third conductor elements of successive thermocouples alternately face each other. The conductor elements that face each other in the bank are electrically connected with each other' and the second conductor elements of the thermocouples are alternately made of conductive material that is thermoelectrically positive and thermoelectrically negative with respect to the conductive material of the first and third conductor elements.

The invention concerns a device for producing electric energy with a plurality of thermocouples, each of which has a first conductor element, a second conductor element connected with the first conductor element, and a third conductor element connected with the second conductor element on the opposite side of the second conductor element from the first conductor element, wherein the conductive material of the first and third conductor elements is different from the conductive material of the second conductor elements; the first conductor elements are connected with a heat source, and the third conductor elements are connected with a heat sink; and a bank of thermocouples is provided, in which the first and third conductor elements of successive thermocouples alternately face each other.

A device of this type for converting thermal energy to electric energy, in which the thermocouples are connected in parallel, is described in DE 102 00 407 A1.

The objective of the invention is to develop a thermoelectric battery of the aforementioned type with increased electric power.

In accordance with the invention, the conductor elements that face each other in the bank are electrically connected with each other, and the second conductor elements of the thermocouples are alternately made of a conductive material that is thermoelectrically positive and thermoelectrically negative with respect to the conductive material of the first and third conductor elements.

Alternatively, the conductor elements that face each other can be electrically insulated from each other, and each of the third conductor elements can be electrically connected with the first conductor element of the following thermocouple in the bank.

In both alternative embodiments, the thermoelectric voltages of adjacent thermocouples in the bank are unidirectional and cumulative. A thermoelectric battery of this type makes it possible to arrange junctions at different temperatures between conductors in spatially high density and in this way to achieve increased electric power.

The conductor elements that face each other in the bank and are electrically connected with each other can directly merge with each other, i.e., can be provided as a single piece, and conductor elements of this type are preferably formed by a plate.

A large number of second conductor elements can be arranged between each of the plates that form a stacked arrangement, so that in addition to a series connection of thermocouples, a parallel connection is also present, which reduces the internal resistance and increases the electric power.

In an especially preferred embodiment of the invention, the second conductor elements alternately consist of a p-type and an n-type semiconductor.

The second conductor elements or semiconductors can be block-like parts, which are connected by a contact surface that corresponds to their cross-sectional area with the first and second conductor elements, preferably plates that form these conductor elements.

A connection to the heat source or the heat sink can be produced by thermally conductive rods that pass through the stacked arrangement, such that the thermally conductive rods are guided through aligned, successive openings in the plates, alternately in thermal contact with the edge of the opening and thermally insulated from the edge of the opening, preferably at some distance from the edge of the opening. Accordingly, heated and cooled plates alternate with each other in the stacked arrangement.

In the preferred embodiment of the invention, the thermally conductive rods are in thermal contact with the edge of the opening via electrically insulating thermally conductive rings, such that the rings are preferably stepped and can be supported on the edge of the opening. Alternatively, a plate could have openings with different widths, and the edge of the narrower openings could be in direct contact with the thermally conductive rod.

The use of thermally conductive rods in which a heat-transfer medium flows is preferred. This heat convection allows the heat to be supplied or removed significantly more effectively than heat conduction alone. Especially heat pipes or other high-efficiency conveying devices can be used as thermally conductive rods.

It is advantageous for the contact surfaces of the p-type and n-type semiconductors to be square and for the openings in the plates or foils to be circular. In an especially preferred embodiment, the openings in the plates are arranged in a square grid pattern, and the extended diagonals of the contact surfaces of the p-type and n-type semiconductors bisect the sides of the squares. In this arrangement, the available plate surface is largely used as a contact surface, and a high packing density of the alternately hot and cold junctions can be achieved, such that the hot and cold junctions within the stacked arrangement have a uniformly higher or lower temperature.

In the corner regions, the contact surfaces can overlap, and the semiconductors each have corresponding recesses at two corners.

In a further refinement of the invention, the aforementioned plates consist of several layers. In this way, plates with, for example, p-type or n-type semiconductors and layers on the upper side and lower side can be prefabricated, which facilitates the assembly of the device.

To join the p-type and n-type semiconductors with the plates or layers and to join the layers with each other, it is advantageous to use an adhesive bonding technique with conductive adhesives. In addition to adhesive bonding techniques, it is also possible to use welding techniques, bonding techniques, and other suitable joining methods.

It is advantageous for the free ends of the thermally conductive rods at the opposite end from the heat source or heat sink to terminate in or on a layer of insulation, which is provided between the source or the sink and the stacked arrangement and serves as both electrical and thermal insulation.

The invention will now be explained in greater detail with reference to the embodiments illustrated in the accompanying drawings.

FIG. 1 shows a schematic representation of a thermocouple elementary cell formed by semiconductors.

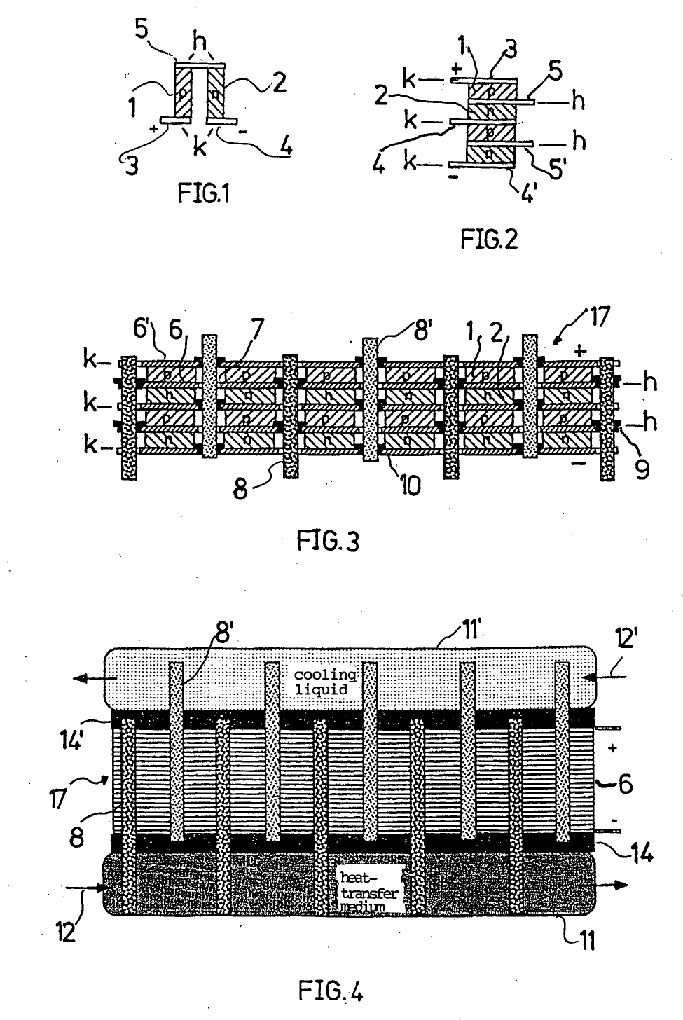

FIG. 2 shows a series connection of elementary cells in accordance with FIG. 1.

FIG. 3 shows an arrangement of elementary cells connected in parallel and in series.

FIG. 4 shows a thermoelectric battery that uses the arrangement of FIG. 3 in accordance with a first embodiment of the present invention.

FIG. 5 shows a section of the plate used in the thermoelectric battery of FIG. 4.

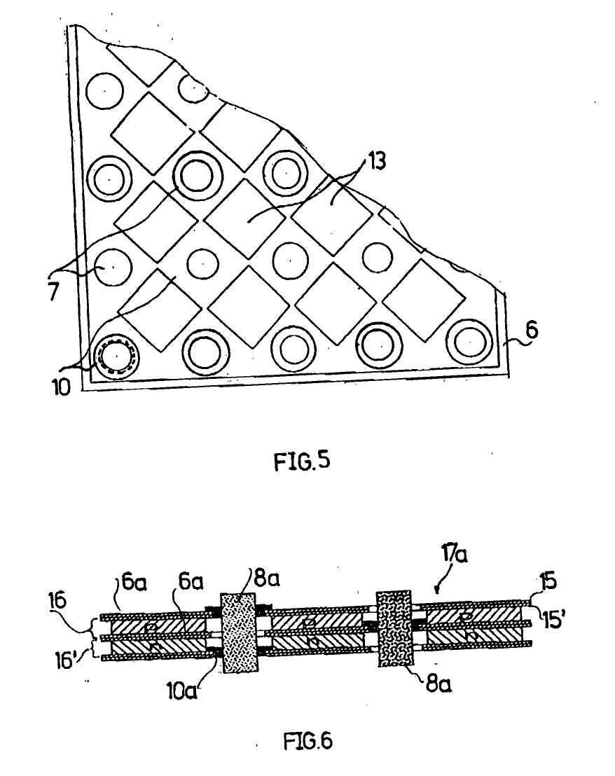

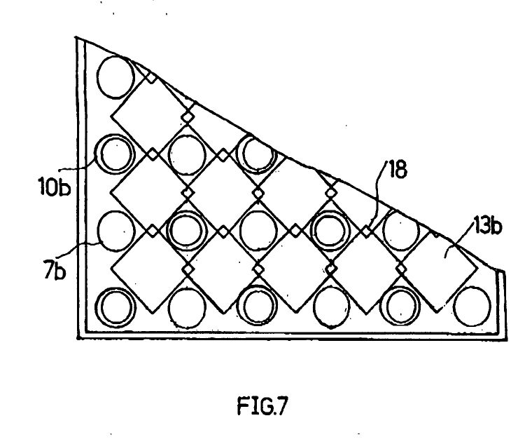

FIG. 6 shows an arrangement of elementary cells connected in parallel and in series in accordance with a second embodiment of the invention.

FIG. 7 shows another embodiment of a plate section that can be used in a thermoelectric battery in accordance with the invention.

An elementary cell shown in FIG. 1 to explain the invention has a p-doped semiconductor 1 and an n-doped semiconductor 2. Each of the semiconductors 1 and 2 is connected at one end with a conductor element 3 or 4, respectively, and with each other by a conductor element 5. The conductor elements 3 to 5 are made of the same conductive material, e.g., copper. An electric potential difference develops between the conductor elements 3 and 4 if the temperature at the two thermojunctions of the semiconductors 1 and 2 with the conductor element 5 differs from the temperature at the two thermojunctions of the conductor elements 3 and 4 with the semiconductors. The thermoelectric voltages of the two basic elements of the elementary cell are unidirectional and cumulative.

FIG. 2 shows a bank of two such elementary cells. The thermoelectric voltages of the two cells are cumulative when provision is made to ensure that the junctions between the semiconductors 1, 2, 1′, 2′ and the conductor elements 3, 5, 4, 5′, 4′ are kept at alternately different temperatures, i.e., cold (k) and hot (h).

FIG. 3 shows an arrangement with a plurality of such thermocouple banks connected both in series and in parallel. Congruent plates 6 and 6′, which form a stacked arrangement 17 and have openings 7 arranged in a grid pattern, serve as conductor elements. Thermally conductive rods 8 and 8′ extend through the mutually aligned openings 7; the rods 8 are connected with a heat source, and the rods 8′ are connected with a heat sink. The heat source and heat sink are not shown in FIG. 3.

The alternating plates 6 and 6′ are connected with a thermally conductive rod 8 or 8′ by contact rings 10, which are inserted in the associated openings 7 and are electrically insulated from the plate and/or thermally conductive rods. Each contact ring 10 fills a space between the thermally conductive rod and the edge of the respective opening 7. In other words, the plates 6 are in thermal contact with the heat source via the electrically insulating contact rings 10, and the plates 6′ are in thermal contact with the heat sink.

FIG. 4 shows a complete thermoelectric battery that uses the arrangement of FIG. 3. The p-type and n-type semiconductors between the plates 6 and 6′ are not shown.

As FIG. 4 shows, the thermally conductive rods 8 terminate in a vessel 11 that constitutes the heat source. A liquid heat-transfer medium flows through the vessel 11 as indicated by the arrow 12. The thermally conductive rods 8′ are in thermal contact with a cooling liquid, which flows through a vessel 11′ that constitutes the heat sink as indicated by the arrow 12′. The vessels 11, 11′ and the stacked arrangement 17 comprising the plates 6 and 6′, between which p-type and n-type semiconductors are alternately arranged, are separated from each other by a thermally and electrically insulating layer 14 and 14′, respectively.

In the thermoelectric battery described above, the plates 6 and the plates 6′ are maintained at different temperatures by the vessel 11 and the vessel 11′ respectively. Correspondingly different temperatures prevail at the flat junctions between the p-type and n-type semiconductors and the respective plates 6 and 6′. A thermoelectric voltage that is a multiple of the thermoelectric voltage delivered by a single elementary cell in accordance with FIG. 1 develops between the two outermost plates of the stacked arrangement 14 by series connection of a large number of thermocouples. Due to additional parallel connection of many cells with flat-contacting semiconductors, the internal resistance of the thermoelectric battery is low, so that a strong current can flow, and high electric power can be delivered.

In the embodiment shown here, the thermally conductive rods 8, 8′ are designed as hollow bodies that contain a heat-transfer medium, so that in addition to heat conduction, even more effective heat transfer occurs by convection. Heat pipes, in which a heat-transfer medium alternates between the gas phase and the liquid phase, are especially suitable as thermally conductive rods.

In the illustrated embodiment, the plates 6, 6′ and the p-type and n-type semiconductors are adhesively bonded by an electrically conductive adhesive. Connection can also be achieved by bonding techniques, welding techniques, and similar joining techniques. In addition, a diffusion barrier layer, which prevents excessive diffusion of doping material into the plates 6, 6′, is formed on the contact surfaces of the semiconductors.

A retaining device for stabilizing the arrangement, which engages the outside of the each vessel 11, 11′ and has plates connected with each other by tension rods, is not shown in the drawings.

FIG. 5 shows a section of a plate 6 or 6′ with openings 7 and contact rings 10 inserted in some of the openings and contact surfaces 13 for connection with p-type or n-type semiconductors. The contact surfaces could be bounded by the edges of impressions. As FIG. 5 shows, the semiconductors have a square cross section. The cross-sectional shape could also be something other than square, especially circular. This cross-sectional shape and the illustrated manner of arrangement of hot and cold junctions allows the greatest possible packing density of the junctions in the stacked arrangement.

The thermal contact rings 10 have a shoulder 9 with an inside diameter that is the same as the diameter of the openings 7.

It is understood that the free openings 7 on the plates 6 are occupied by contact rings on the plates 6′.

In the illustrated embodiment, the plates 6, 6′ are made of copper, the thermal contact rings are made of aluminum, and the outer casing of the thermally conductive rods 8, 8′ are made of aluminum, copper, or some other thermally conductive material. Oxidized surfaces can be used for mutual electrical insulation of these parts.

BiTe is an example of a possible semiconductor material.

In the following discussion of the other figures, parts that are the same or have the same function are labeled with the same reference number but with the letter “a” or “b” appended.

In the embodiment of FIG. 6, each of the plates 6a and 6a′ of a stacked arrangement 17a consists of two layers 15 and 15′, which can be joined with each other in the assembled thermoelectric battery by conductive adhesive, welding techniques, bonding techniques, and the like. This embodiment has the advantage that plates 16 with p-type semiconductors and plates 16′ with n-type semiconductors can be completely prefabricated.

FIG. 7 shows another possibility for forming plates 6b and 6b′. In the corner region 18, overlapping contact surfaces 13b for p-type and n-type semiconductors are provided, each of which has a recess at two corners that corresponds to the junction point. This type of arrangement makes it possible to achieve an even greater total contact surface and thus an even lower internal resistance of the thermoelectric battery.

1. Device for producing electric energy with a plurality of thermocouples, each of which has a first conductor element (6), a second conductor element (1; 2) connected with the first conductor element, and a third conductor element (6′) connected with the second conductor element (1; 2) on the opposite side of the second conductor element from the first conductor element (6), wherein the conductive material of the first and third conductor elements (6, 6′) is different from the conductive material of the second conductor elements (1; 2); the first conductor elements (6) are connected with a heat source (11), and the third conductor elements (6′) are connected with a heat sink (11′); and a bank of thermocouples is provided, in which the first (6) and third (6′) conductor elements of successive thermocouples alternately face each other, wherein the conductor elements that face each other in the bank are electrically connected with each other, and the second conductor elements (1; 2) of the thermocouples are alternately made of a conductive material that is thermoelectrically positive and thermoelectrically negative with respect to the conductive material of the second and third conductor elements (6, 6′), or that the conductor elements that face each other in the bank are electrically insulated from each other, and each of the third conductor elements is electrically connected with the first conductor element of the following thermocouple in the bank.

2. Device in accordance with claim 1, wherein the conductor elements (6, 6′) that face each other in the bank and are electrically connected with each other directly merge with each other.

3. Device in accordance with claim 1, wherein the conductor elements that face each other in the bank and are electrically connected with each other are each formed by a single plate (6, 6′).

4. Device in accordance with claim 3, wherein a plurality of second conductor elements (1; 2) is arranged between the plates (6, 6′) that form a stacked arrangement (17).

5. Device in accordance with claim 1, wherein the second conductor elements (1; 2) alternately consist of a p-type (1) and an n-type (2) semiconductor.

6. Device in accordance with claim 1, wherein the second conductor elements (1; 2) have a block-like design and are electrically connected by a contact surface that corresponds to the cross-sectional area with the first (6) and third (6′) conductor element of each thermocouple.

7. Device in accordance with claim 3, wherein the plates (6, 6′) are connected with the heat source (11) or heat sink (11′) by thermally conductive rods (8, 8′) that pass through the stacked arrangement (17), such that the thermally conductive rods (8, 8′) are guided through aligned, successive openings (7) in the plates (6, 6′), and such that the thermally conductive rods (8, 8′) are alternately guided through the openings (7) in thermal contact with the edge of the opening and thermally insulated from the edge of the opening, preferably at some distance from the edge of the opening.

8. Device in accordance with claim 7, wherein the thermally conductive rods (8, 8′) are in thermal contact with the edge of the opening either directly or through electrically insulating thermally conductive rings (10).

9. Device in accordance with claim 7, wherein a heat-transfer medium flows in the thermally conductive rods (8, 8′).

10. Device in accordance with claim 7, wherein the contact surfaces (13) of the second conductor elements (1; 2) are square and the openings (7) are circular, or, vice versa, the contact surfaces are circular and the openings are square.

11. Device in accordance with claim 10, wherein the openings (7) in the plates (6, 6′) are arranged in a preferably square grid pattern and possibly the extended diagonals of the contact surfaces (13) of the p-type and n-type semiconductors bisect the sides of the squares.

12. Device in accordance with claim 10, wherein overlapping contact surfaces (13b) are provided in corner regions (18).

13. Device in accordance with claim 1, wherein the plates (6a, 6a′) consist of several layers (15, 15′).

14. Device in accordance with claim 3, wherein the second conductor elements (1; 2) are joined with the plates (6, 6′), especially by a conductive adhesive.

15. Device in accordance with claim 1, wherein the ends of the thermally conductive rods (8, 8′) at the opposite end from the heat source (11) or heat sink (11′) terminate in or on a layer of insulation (14, 14′), which is provided between the source or the sink and the stacked arrangement (17).
